(19) United States
(12) Patent Application Publication
(10) Pub. No.: US 2024/0164180 A1
(43) Pub. Date: May 16, 2024

(54) DISPLAY DEVICE

(71) Applicant: LG ELECTRONICS INC., Seoul (KR)

(72) Inventors: Doyoung KIM, Seoul (KR); Byungkil LIM, Seoul (KR); Seokjung KANG, Seoul (KR)

(73) Assignee: LG ELECTRONICS INC., Seoul (KR)

(21) Appl. No.: 18/491,996

(22) Filed: Oct. 23, 2023

(30) Foreign Application Priority Data
Nov. 11, 2022 (KR) 10-2022-0150183

(51) Int. Cl. H10K 59/80

(52) U.S. Cl. CPC H10K 59/872; H10K 59/873

(57) ABSTRACT

A display device is provided. The display device according to the present disclosure includes: a display panel having at least one corner; a side frame including a horizontal part extending along one side of the display panel from the at least one corner and facing a rear surface of the display panel, and a vertical part extending in a direction intersecting the horizontal part and covering the one side of the display panel; and a hygroscopic member making contact with the vertical part and fixed to the horizontal part at a position between the rear surface of the display panel, which is adjacent to the at least one corner, and the horizontal part of the side frame.

### CROSS-REFERENCE TO RELATED APPLICATION

Pursuant to 35 U.S.C. § 119, this application claims the benefit of earlier filing date and right of priority to Korean Application No. 10-2022-0150183, filed on Nov. 11, 2022, the contents of which are all incorporated by reference herein in their entirety.

### BACKGROUND OF THE INVENTION

### 1. Field of the Invention

The following description relates to a display device.

### 2. Description of the Related Art

With the development of the information society, there have been growing demands for various types of display devices, and in order to meet these demands, various display devices, such as a liquid crystal display (LCD), a plasma display panel (PDP), an electroluminescent display (ELD), a vacuum fluorescent display (VFD), an organic light emitting diode (OLED), etc., have been studied and used recently.

Among these devices, the LCD panel includes a TFT substrate and a color substrate which are positioned opposite each other with a liquid crystal layer interposed therebetween, and displays images by using light provided by a backlight unit. Further, the OLED panel may display images by using a self-emitting organic layer deposited on a substrate on which transparent electrodes are formed.

Particularly, in comparison with a display device using the LCD panel, a display device using the OLED panel has excellent luminance and viewing angle characteristics and does not require a backlight unit, such that the OLED display device can be implemented as an ultra-thin display device.

Recently, a large-screen, ultra-thin display device is being actively researched.

### SUMMARY OF THE INVENTION

It is an objective of the present disclosure to solve the above and other problems.

It is another objective of the present disclosure to ensure structural rigidity of an ultra-thin display device.

It is yet another objective of the present disclosure to provide a display device capable of preventing damage to a display panel.

In accordance with an aspect of the present disclosure, the above and other objectives can be accomplished by providing a display device including: a display panel having at least one corner; a side frame including a horizontal part extending along one side of the display panel from the at least one corner and facing a rear surface of the display panel, and a vertical part extending in a direction intersecting the horizontal part and covering the one side of the display panel; and a absorbing member making contact with the vertical part and fixed to the horizontal part at a position between the rear surface of the display panel, which is adjacent to the at least one corner, and the horizontal part of the side frame.

### Effects of the Invention

The display device according to the present disclosure has the following effects.

According to at least one of the embodiments of the present disclosure, structural rigidity of a large-screen, ultra-thin display device may be ensured.

According to at least one of the embodiments of the present disclosure, a display device capable of preventing damage to a display panel may be provided.

Further scope of applicability of the present disclosure will become apparent from the detailed description given hereinafter. However, it should be understood that the detailed description and specific examples, while indicating preferred embodiments of the present disclosure, are given by illustration only, since various changes and modifications within the spirit and scope of the present disclosure will become apparent to those skilled in the art from this detailed description.

### BRIEF DESCRIPTION OF THE DRAWINGS

FIGS. 1 to 27 are diagrams illustrating examples of a display device according to embodiments of the present disclosure.

### DETAILED DESCRIPTION OF THE PREFERRED EMBODIMENTS

Hereinafter, the present disclosure will be described in detail with reference to the accompanying drawings, in which the same reference numerals are used throughout the drawings to designate the same or similar components, and a redundant description thereof will be omitted.

The suffixes, such as “module” and “unit,” for elements used in the following description are given simply in view of the ease of the description, and do not have a distinguishing meaning or role.

In addition, it will be noted that a detailed description of known arts will be omitted if it is determined that the detailed description of the known arts can obscure the embodiments of the present disclosure. Further, the accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms, “first,” “second,” etc., may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A singular representation may include a plural representation unless context clearly indicates otherwise.

It should be understood that the terms, “comprise,” “include,” “have,” etc. when used in this specification, specify the presence of stated features, integers, steps, operations, elements, components, or combinations thereof but do not preclude the presence or addition of one or more other features, integers, steps, operations, elements, components, or combinations thereof.

References to directions, such as up (U), down (D), left (Le), right (Ri), front (F), and rear (R), shown in the drawings are provided merely for convenience of explanation and are not intended for limiting the scope of the present disclosure.

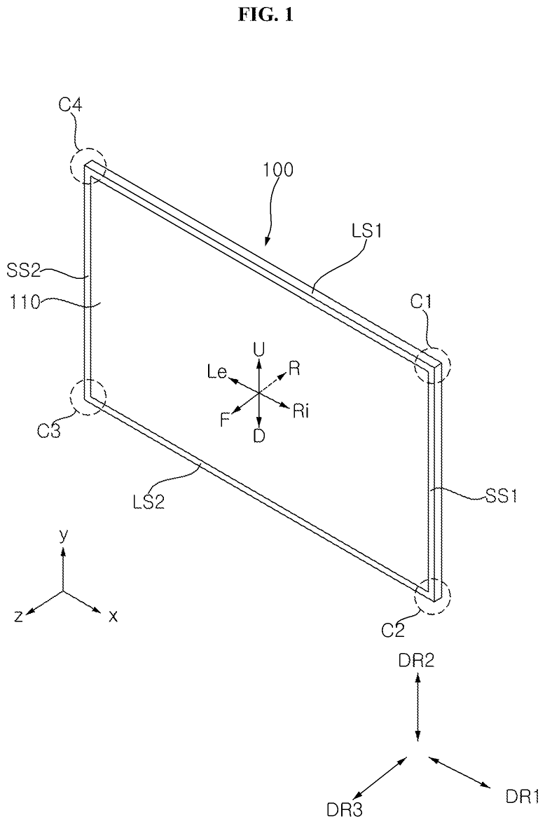

Referring to FIG. 1, a display device 100 may include a display panel 110. The display panel 110 may display images.

The display device 100 may include a first long side LS1, a second long side LS2 opposite to the first long side LS1, a first short side SS1 adjacent to the first long side LS1 and the second long side LS2, and a second short side SS2 opposite to the first short side SS1. For convenience of explanation, it is illustrated and described that the first and second long sides LS1 and LS2 are longer than the first and second short sides SS1 and SS2, but it is also possible that lengths of the first and second long sides LS1 and LS2 may be approximately equal to lengths of the first and second short sides SS1 and SS2.

A direction parallel to the long sides LS1 and LS2 of the display device 100 may be referred to as a first direction DR1 or a left-right direction. A direction parallel to the short sides SS1 and SS2 of the display device 100 may be referred to as a second direction DR2 or an up-down direction UD. A direction perpendicular to the long sides LS1 and LS2 and the short sides SS1 and SS2 of the display device 100 may be referred to as a third direction DR3 or a front-rear direction FR.

A side on which the display device 100 displays an image may be referred to as a front side F, +z, and a side opposite thereto may be referred to as a rear side R, −z. The second short side SS2 may be referred to as a left side Le, −x, and the first short side SS1 may be referred to as a right side Ri, +x. The first long side LS1 may be referred to as an upper side U, +y, and the second long side LS2 may be referred to as a lower side D, −y.

The first long side LS1, the second long side LS2, the first short side SS1, and the second short side SS2 may be referred to as edges of the display device 100. Further, positions where the first long side LS1, the second long side LS2, the first short side SS1, and the second short side SS2 meet each other may be referred to as corners.

A position where the first short side SS1 and the first long side LS1 meet each other may be referred to as a first corner C1. A position where the first short side SS1 and the second long side LS2 meet each other may be referred to as a second corner C2. A position where the second short side SS2 and the second long side LS2 meet each other may be referred to as a third corner C3. A position where the second short side SS2 and the first long side LS1 meet each other may be referred to as a fourth corner C4.

Hereinafter, the display panel 110 will be described using an Organic Light Emitting Diode (OLED) display panel as an example, but the type of the display panel 110 which may be applied to the present disclosure is not limited thereto.

The display panel 110 may form a front surface of the display device 100 and may display images on the front side. The display panel 110 may divide an image into a plurality of pixels and may output the image while controlling color, brightness, and chroma of the respective pixels. The display panel 110 may be divided into an active area, in which the image is displayed, and a de-active area in which the image is not displayed. The display panel 110 may generate light corresponding to red, green, or blue color in response to a control signal.

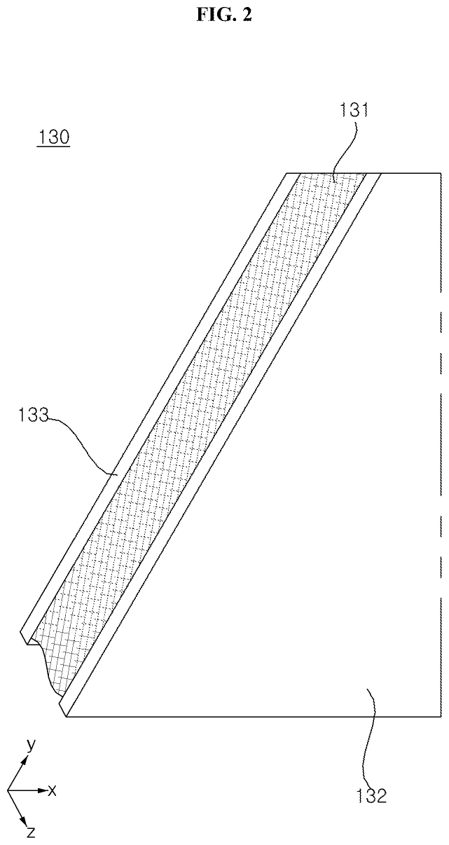

Referring to FIG. 2, a material complexed panel 130 may include a core 131, a front skin 132, and a rear skin 133. The core 131, the front skin 132, and the rear skin 133 may be bonded to each other. The material complexed panel 130 may be referred to as a fiber complexed panel 130, a fiber complexed plate 130, a material complexed plate 130, or a frame 130.

The front skin 132 may form a front surface of the material complexed panel 130. The rear skin 133 may form a rear surface of the material complexed panel 130. The front skin 132 and the rear skin 133 may include a metal material. For example, the front skin 132 and the rear skin 133 may include aluminum (Al). In another example, the front skin 132 and the rear skin 133 may be galvanized iron (Galvanized Steel Sheet). For example, the front skin 132 and the rear skin 133 may have a thickness of about 0.5 mm. The front skin 132 and the rear skin 133 may be disposed opposite each other with respect to the core 131.

The core 131 may be disposed between the front skin 132 and the rear skin 133. The core 131 may include fibers. The core 131 may be made of a composite material. The core 131 may include a main fiber and a binder fiber. The binder fiber may be mixed into the main fiber.

A hot-melt sheet may be disposed between the front skin 132 and the core 131. In addition, the hot-melt sheet may be disposed between the rear skin 133 and the core 131. The hot-melt sheet may be a film. For example, the hot-melt sheet may be a film, such as EVA, acryl, polyurethane, etc., which has a thickness of 50 μm or more. The core 131 and the hot-melt sheets may be laminated on the front skin 132 and the rear skin 133 at a high temperature (e.g., about 190° C. to 200° C.) for one minute or more.

Accordingly, the material complexed panel 130 may improve bending stiffness and/or torsional stiffness of the display device.

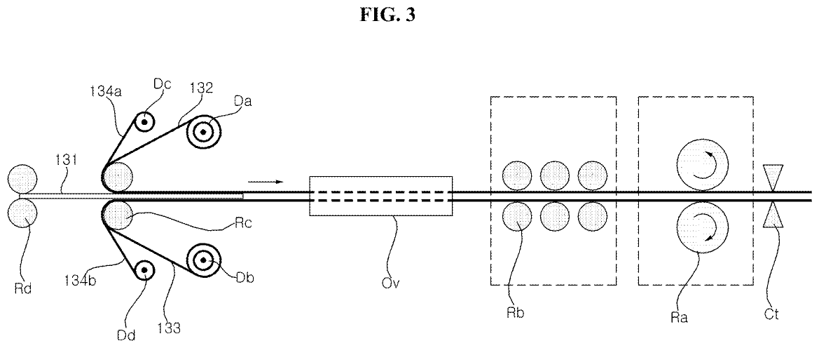

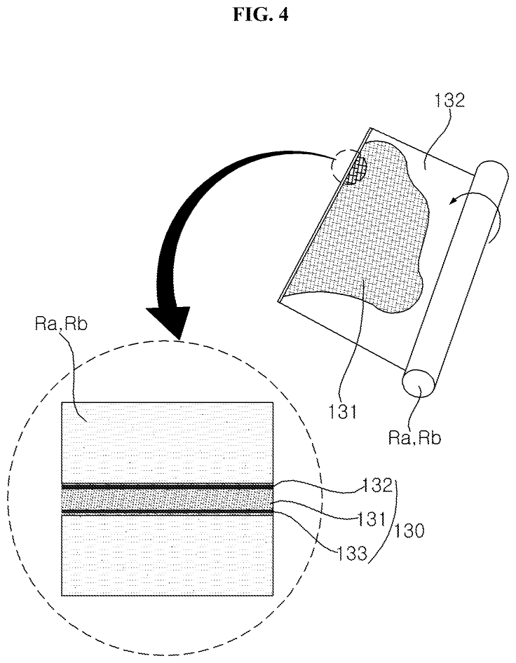

Referring to FIGS. 3 and 4, the material complexed panel 130 may be produced by pressing the front skin 132 and the rear skin 133 to the core 131 using a plurality of rollers, and this process may be referred to as a roll-to-roll (R2R) process.

Referring to FIG. 3, by rotation of a pinch roller Ra that serves as a driving motor, the front skin 132 is unwound from a front drum Da, the rear skin 133 is unwound from a rear drum Db, and the core 131 moves through a feeding roller Rd. Then, a first adhesive 134a for bonding the front skin 132 to the core 131 may be unwound from the first drum Dc. In addition, a second adhesive 134b for bonding the rear skin 133 to the core 131 may be unwound from the second drum Db. In this case, the front skin 132, the first adhesive 134a, the core 131, the second adhesive 134b, and the rear skin 133 may be laminated in this order and may be guided by a guide roller Rc toward an oven Ov. The adhesives 134a and 134b may be hot-melt sheets 134a and 134b.

The first and second adhesives 134a and 134b are melted in the oven Ov to allow the front skin 132 and the rear skin 133 to be bonded to the core 131. For example, the first and second adhesives 134a and 134b may have a melting point of about 150° C., and ambient temperature of the oven Ov may be about 200° C. For example, the first and second adhesives 134a and 134b may have a peel-off force of about 10 kgf or more.

After passing through the oven Ov, the front skin 132, the core 131, and the rear skin 133 may be guided to a pressure roller Rb by the rotation of the pinch roller Ra and may be pressed by the pressure roller Rb, thereby further strengthening the bonding force between the front skin 132, the core 131, and the rear skin 133. The front skin 132, the core 131, and the rear skin 133 which are bonded together pass through the pinch roller Ra, and then are cut by a cutter Ct, such that the material complexed panel 130 may be manufactured in a predetermined size.

Referring to FIG. 4, the pressure roller Rb or the pinch roller Ra may make contact with an outer surface of each of the front skin 132 and the rear skin 133. When the pressure roller Rb or the pinch roller Ra rotates, the material complexed panel 130 may move in a longitudinal direction of the core 131. In this case, the front skin 132 and the rear skin 133 may be bonded to the core 131 sequentially from a first end to a second end of the core 131 in the longitudinal direction of the core 131.

In addition, the front skin 132 and the rear skin 133 of the material complexed panel 130 may be formed flat. That is, a rear surface of the rear skin 133 that forms a rear surface of the display device 100 is formed flat, thereby facilitating an additional process of coating the rear surface of the rear skin 133 or attaching a sheet thereto or the like for the exterior aesthetics. Alternatively, the rear skin 133 which is flat, may form itself the rear surface of the display device 100.

In addition to using the roll-to-roll (R2R) process described above with reference to FIGS. 3 and 4, the material complexed panel 130 may be produced by a process of sequentially laminating and bonding the front skin 132, the core 131, and the rear skin 133, and the like.

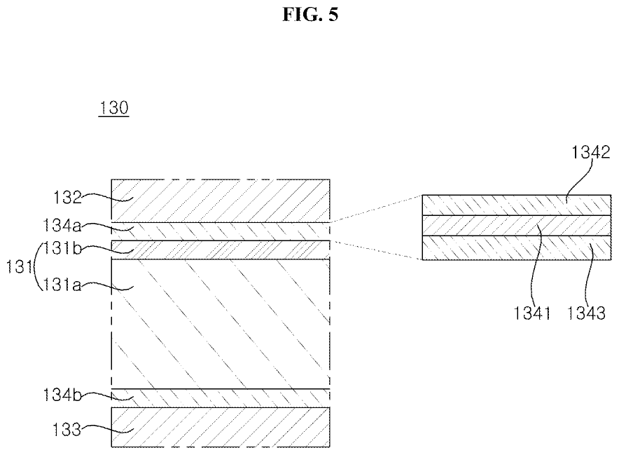

Referring to FIG. 5, the core 131 may include a main core 131a and a binder core 131b. The main core 131a may include a first fiber made of polyethylene terephthalate (PET) and a second fiber made of long material (LM). For example, each of the first fiber and the second fiber accounts for 50% of the main core 131a. The binder core 131b may include an acrylic fiber.

The front skin 132 may include aluminum (Al) or Galvanized Iron and may be bonded to the binder core 131b by the first hot-melt adhesive 134a.

The rear skin 133 may include aluminum (Al) or Galvanized Iron and may be bonded to the main core 131a by the second hot-melt adhesive 134b.

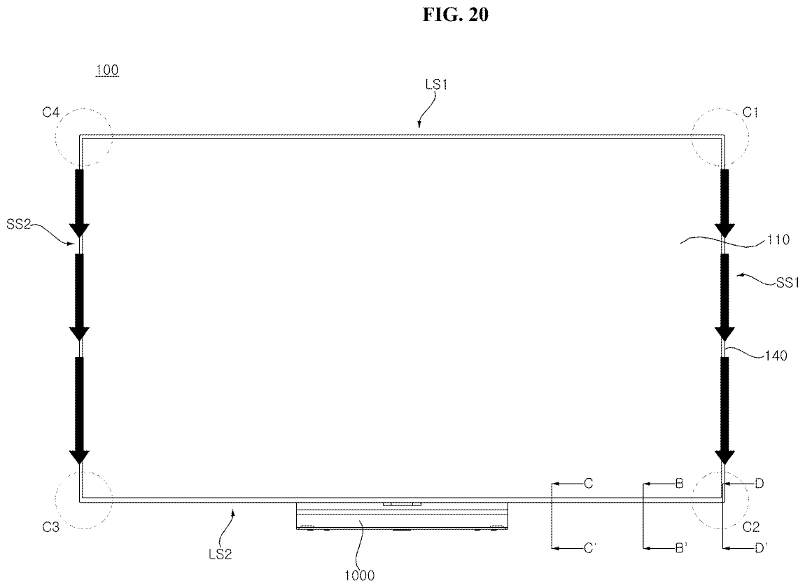

The front skin 132 may be disposed closer to the display panel 110 (see FIG. 20) than the rear skin 133 and may be exposed to a relatively high-temperature environment compared to the rear skin 133. That is, a temperature difference may occur between the front skin 132 and the rear skin 133. For example, there may be a temperature difference of about 4° C. between the front skin 132 and the rea skin 133.

In this case, the hot-melt adhesives 134a and 134b may have a structure of multiple layers of fabric material. The hot-melt adhesives 134a and 134b may include a first layer 1341, a second layer 1342, and a third layer 1343. For example, the first layer 1341, the second layer 1342, and the third layer 1343 may include synthetic fiber material. For example, the first layer 1341 may include a nylon material and may be disposed between the second layer 1342 and the third layer 1343. For example, the second layer 1342 and the third layer 1343 may include a polyurethane (PU) material.

Accordingly, elongation properties of the respective layers of the material complexed panel 130 may minimize bending of the material complexed panel 130, which is caused by thermal deformation due to a temperature difference between the front skin 132 and the rear skin 133.

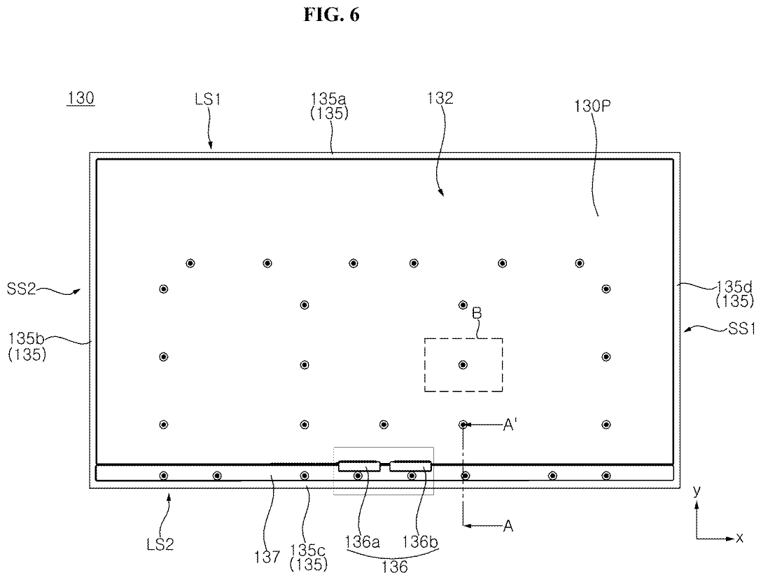

Referring to FIG. 6, the material complexed panel 130 may include a flat plate part 130P, an outer part 135, and a receiving part 137. The front skin 132 of the material complexed panel 130 may define a front surface of each of the flat plate part 130P, the outer part 135, and the receiving part 137.

The outer part 135 may be formed on a periphery of the flat plate part 130P. The outer part 135 may be formed by being pressed rearward from the flat plate part 130P. A first outer part 135a may be formed along an upper side of the flat plate part 130P. A second outer part 135b may be formed along a right side of the flat plate part 130P. A third outer part 135c may be formed along a lower side of the flat plate part 130P. A fourth outer part 135d may be formed along a left side of the flat plate part 130P.

The receiving part 137 may be formed between the flat plate part 130P and the third outer part 135c. The receiving part 137 may be formed by being pressed rearward from the flat plate part 130P and/or the third outer part 135c.

The cable hole 136 may be formed through the receiving part 137 in a front-rear direction. For example, a plurality of cable holes 136a and 136b may be next to each other.

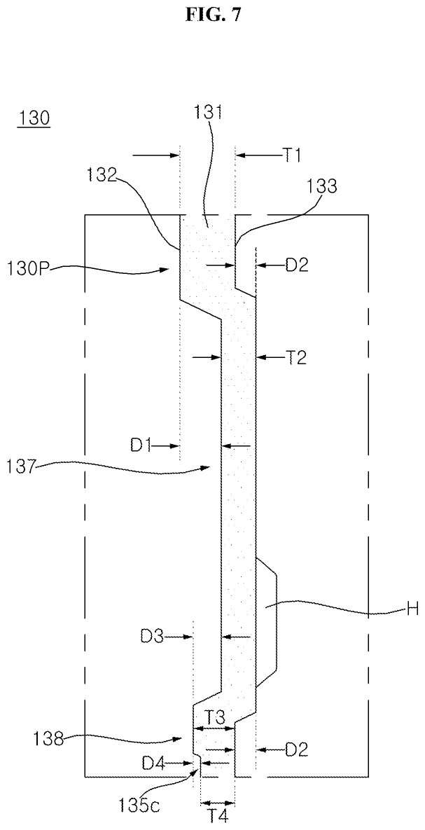

Referring to FIG. 7, a thickness T1 of the flat plate part 130P may be greater than a thickness T2 of the receiving part 137. A step D1 between the front skin 132 of the flat plate part 130P and the front skin 132 of the receiving part 137 may be greater than a step D2 between the rear skin 133 of the flat plate part 130P and the rear skin 133 of the receiving part 137.

A thickness T4 of the third outer part 135c may be greater than the thickness T2 of the receiving part 137. The step D2 between the rear skin 133 of the third outer part 135c and the rear skin 133 of the receiving part 137 may be equal to the step D2 between the rear skin 133 of the flat plate part 130P and the rear skin 133 of the receiving part 137.

A protruding pad 138 may protrude forward from the front skin 132 of the third outer part 135c. A thickness T3 of the protruding pad 138 may be greater than the thickness T4 of the third outer part 135c, may be greater than the thickness T2 of the receiving part 137, and may be smaller than the thickness T1 of the flat plate part 130P. A step D4 between the front skin 132 of the protruding pad 138 and the front skin 132 of the third outer part 135c may be smaller than the steps D1, D2, and D3. The step D3, which is stepped downward from the front skin 132 of the protruding pad 138 to the front skin 132 of the receiving part 137, may be smaller than the step D1 and greater than the step D2.

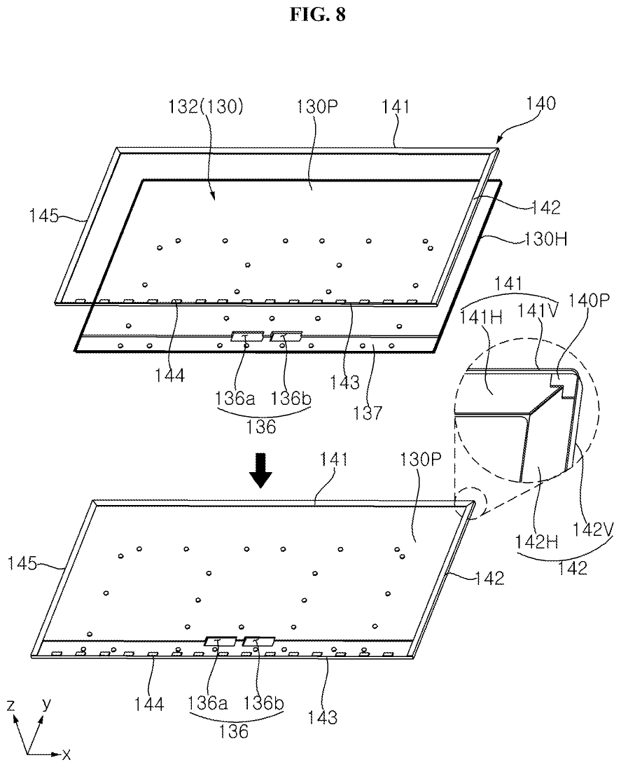

Referring to FIG. 8, a side frame 140 may extend around a periphery of the material complexed panel 130. The side frame 140 may be bonded to the front skin 132 of the outer part 135 (see FIG. 6) of the material complexed panel 130 by a hot-melt adhesive 130H. For example, the side frame 140 may include a metal material such as aluminum (Al). The side frame 140 may be referred to as a guide panel 140 or a middle cabinet 140.

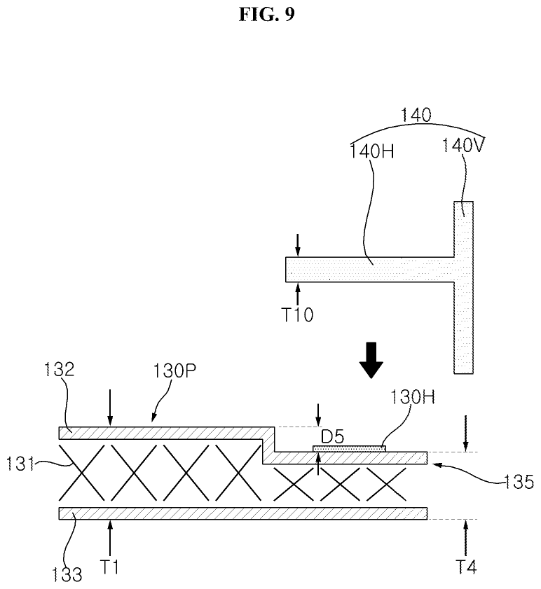

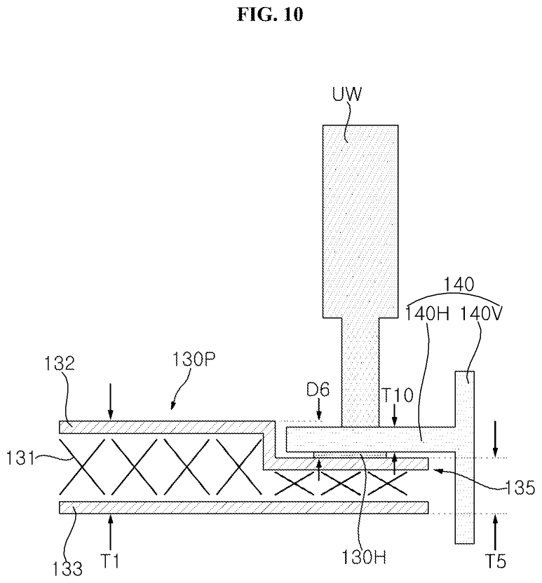

Referring to FIGS. 9 and 10, the side frame 140 may include a vertical part 140V and a horizontal part 140H. The vertical part 140V may extend in a front-rear direction and may cover a side surface of the material complexed panel 130. The horizontal part 140H may extend in a direction intersecting the vertical part 140V and may be disposed at the front of the outer part 135.

Referring to FIG. 9, the outer part 135 may be formed by being pressed rearward from the front skin 132 of the flat plate part 130P. For example, the outer part 135 may be flattened by forging followed by re-striking. For example, the thickness T1 of the flat plate part 130P may be 4.0 mm, and the thickness T4 of the outer part 135 may be 3.0 mm. The hot-melt adhesive 130H may be coated on the outer part 135 and may be disposed between the outer part 135 and the horizontal part 140H.

Referring to FIG. 10, a horn UW of an ultrasonic welder may be disposed on a front surface of the horizontal part 140H and may apply ultrasonic vibrations to the horizontal part 140H and the hot-melt adhesive 130H. Accordingly, the horizontal part 140H may be ultrasonic-welded to the outer part 135 by the hot-melt adhesive 130H. In this case, the front skin 132 of the outer part 135 may be pressed by the horn UW toward the rear skin 133, and a thickness T5 of the outer part 135 may be reduced. For example, the thickness T5 of the outer part 135 may range from 2.4 mm to 2.5 mm. A pressed amount D6-D5 of the outer part 135 pressed by the horn UW may range from 0.5 mm to 0.6 mm. The outer part 135 is pressed during the above ultrasonic welding, i.e., under high-temperature conditions, such that the outer part 135 does not spring back but remains pressed.

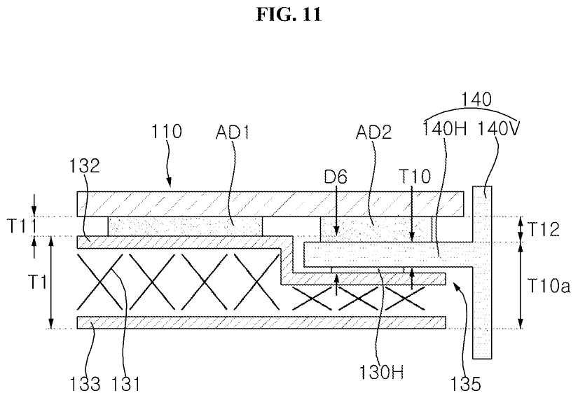

Referring to FIGS. 10 and 11, a sum T10a of the thickness T5 of the outer part 135, the thickness of the hot-melt adhesive 130H, and a thickness T10 of the horizontal part 140H may be less than the thickness T1 of the flat plate part 130P. For example, the thickness T1 of the flat plate part 130P may be 0.4 mm. For example, the thickness T5 of the outer part 135 may range from 2.4 mm to 2.5 mm, the thickness of the hot-melt adhesive 130H may be 0.1 mm, the thickness T10 of the horizontal part 140H may be 1.1 mm, and the sum T10a thereof may range from 3.6 mm to 3.7 mm.

The display panel 110 may be disposed at the front of the horizontal part 140H. A first adhesive member AD1 may be disposed between the front skin 132 of the flat plate part 130P and the rear surface of the display panel 110, and may be bonded to the flat plate part 130P and the display panel 110. For example, a thickness T11 of the first adhesive member AD1 may be 0.5 mm. A second adhesive member AD2 may be disposed between the front surface of the horizontal part 140H and the rear surface of the display panel 110 and may be bonded to the horizontal part 140H and the display panel 110. For example, a thickness T12 of the second adhesive member AD2 may range from 0.8 mm to 0.9 mm. For example, the adhesives AD1 and AD2 may be double-sided tape.

Accordingly, the display panel 110 may be bonded to the material complexed panel 130 and the side frame 140, and may be positioned flat with respect to the material complexed panel 130. In addition, the vertical part 140V may cover a side surface of the display panel 110.

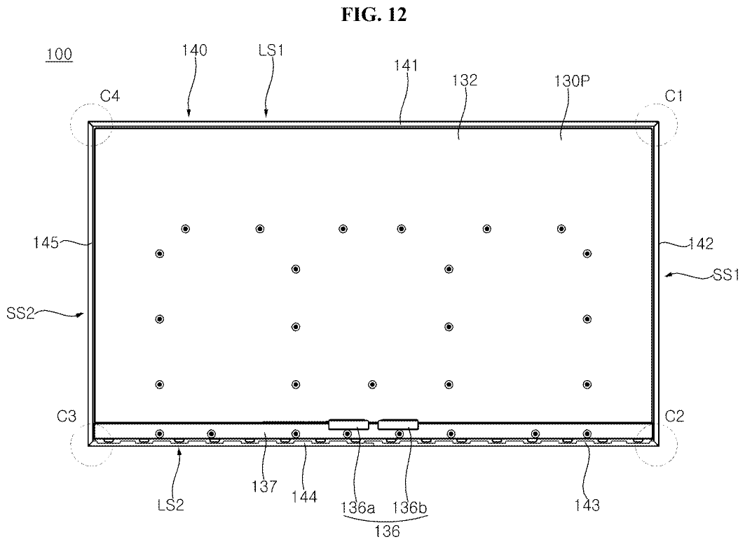

Referring to FIGS. 8 and 12, the side frame 140 may include a first part 141, a second part 142, a third part 143, a fourth part 144, and a fifth part 145.

The first part 141 may extend along the first outer part 135a (see FIG. 6) and may include a first horizontal part 141H (see FIG. 9) and a first vertical part 141V. The first horizontal part 141H may be parallel to the first outer part 135a and may be fixed onto the first outer part 135a by the hot-melt adhesive 130H. The first vertical part 141V may intersect the horizontal part 141H and may cover the top of the material complexed panel 130.

The second part 142 may be bent downward from a right end of the first part 141 (see the first corner C1) and may include a second horizontal part 142H and a second vertical part 142V. The second horizontal part 142H may be parallel to the second outer part 135b and may be fixed onto the second outer part 135b by the hot-melt adhesive 130H. The second vertical part 142V may intersect the second horizontal part 142H and may cover the right side of the material complexed panel 130.

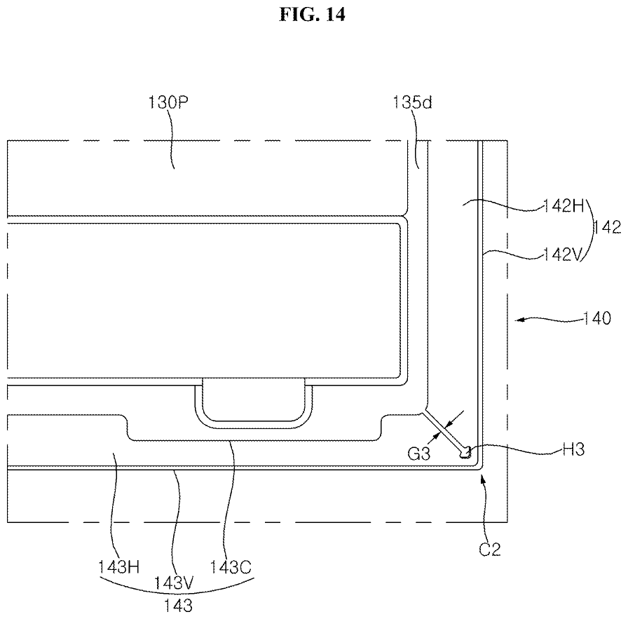

The third part 143 may be bent leftward from a lower end of the second part 142 (see the second corner C2) and may include a third horizontal part 143H (see FIG. 14) and a third vertical part 143V. The third horizontal part 143H may be parallel to the third outer part 135c and may be fixed onto the third outer part 135c by the hot-melt adhesive 130H. The third vertical part 143V may intersect the third horizontal part 143H and may cover the bottom of the material complexed panel 130.

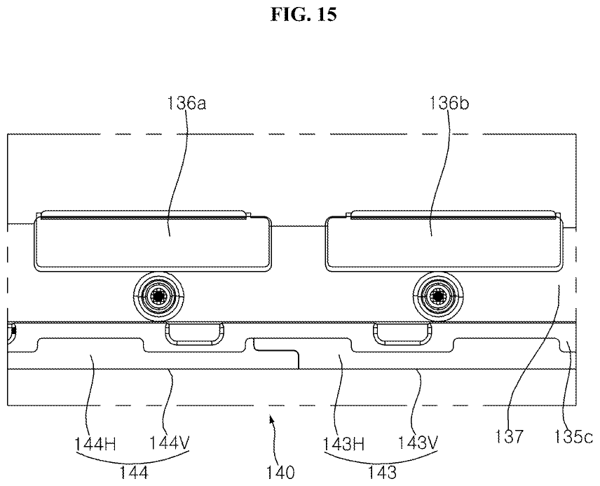

The fourth part 144 may be aligned with the third part 143 along the third outer part 135c, and an end of the fourth part 144 may be connected to an end of the third part 143. The fourth part 144 may include a fourth horizontal part 144H (see FIG. 15) and a fourth vertical part 144V (see FIG. 15). The fourth horizontal part 144H may be parallel to the third outer part 135c and may be fixed onto the third outer part 135c by the hot-melt adhesive 130H. The fourth vertical part 144V may intersect the fourth horizontal part 144H and may cover the bottom of the material complexed panel 130.

The fifth part 145 may be bent downward from a left end of the first part 141 (see the fourth corner C4), and the fourth part 144 may be bent rightward from a lower end of the fifth part 145 (see the third corner C3). The fifth part 145 may include a fifth horizontal part (not shown) and a fifth vertical part (not shown). The fifth horizontal part (not shown) may be parallel to the fourth outer part 135d and may be fixed onto the fourth outer part 135d by the hot-melt adhesive 130H. The fifth vertical part (not shown) may intersect the fifth horizontal part (not shown) and may cover the left side of the material complexed panel 130.

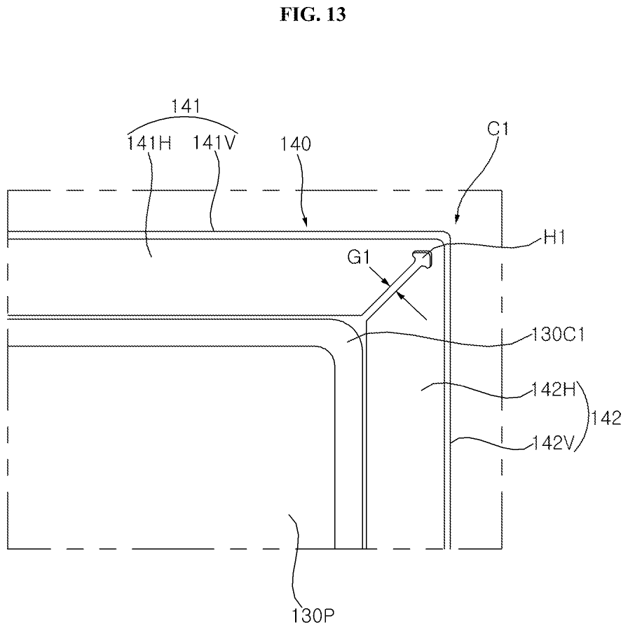

Referring to FIGS. 13 and 14, a gap G1 may be formed between the first horizontal part 141H of the first part 141 and the second horizontal part 142H of the second part 142. The first vertical part 141V of the first part 141 and the second vertical part 142V of the second part 142 may be bent and connected to each other. A hole H1 may be adjacent to the vertical parts 141V and 142V, may be connected to the gap G1, and may have a greater diameter than the gap G1.

In addition, a gap, such as the gap G1, may be formed between the first horizontal part 141H of the first part 141 and the fifth horizontal part (not shown) of the fifth part 145 (see FIG. 12). The first vertical part 141V of the first part 141 and the fifth vertical part (not shown) of the fifth part 142 may be bent and connected to each other. A hole, such as the hole H1, may be adjacent to the first vertical part 141V and the fifth vertical part (not shown).

A gap G3 may be formed between the second horizontal part 142H of the second part 142 and the third horizontal part 143H of the third part 143. The second vertical part 142V of the second part 142 and the third vertical part 143V of the third part 143 may be bent and connected to each other. A hole H3 may be adjacent to the vertical parts 142V and 143V, may be connected to the gap G3, and may have a greater diameter than the gap G3.

In addition, a gap, such as the gap G3, may be formed between the fifth horizontal part (not shown) of the fifth part 145 (see FIG. 12) and the fourth horizontal part 144H (see FIG. 15) of the fourth part 144 (see FIG. 12). The fifth vertical part (not shown) of the fifth part 145 and the fourth vertical part 144V (see FIG. 15) of the fourth part 144 may be bent and connected to each other. A hole, such as the hole H3, may be adjacent to the fifth vertical part (not shown) and the fourth vertical part 144V.

Referring to FIG. 13, a corner 130C1 adjacent to the first corner C1 of the flat plate part 130P may be rounded. For example, a radius of curvature of the corner 130C1 may be 10 mm. Accordingly, it may be advantageous to maintain flatness of a portion (see FIG. 6) adjacent to the first corner C1 between the first outer part 135a and the second outer part 135b in the above process of forging the outer part 135 for the flat plate part 130P and pressing the outer part 135 by using the horn UW (see FIG. 10) of the ultrasonic welder.

In addition, like the corner 130C1, a corner adjacent to the fourth corner C4 (see FIG. 12) of the flat plate part 130P may also be rounded.

Referring to FIG. 14, a corner 130C2 adjacent to the second corner C2 of the flat plate part 130P may be rounded. For example, a radius of curvature of the corner 130C2 may be 10 mm. Accordingly, it may be advantageous to maintain flatness of a portion (see FIG. 6) adjacent to the second corner C2 between the second outer part 135b and the third outer part 135c in the above process of forging the outer part 135 for the flat plate part 130P and pressing the outer part 135 by using the horn UW (see FIG. 10) of the ultrasonic welder.

In addition, like the corner 130C2, a corner adjacent to the third corner C3 (see FIG. 12) of the flat plate part 130P may also be rounded.

Referring to FIG. 15, the third horizontal part 143H of the third part 143 may make contact with the fourth horizontal part 144H of the fourth part 144. The third vertical part 143V of the third part 143 may make contact with the fourth vertical part 144V of the fourth part 144. An end of the third part 143 may be coupled to an end of the fourth part 144. For example, an end of the third part 143 may be welded to an end of the fourth part 144.

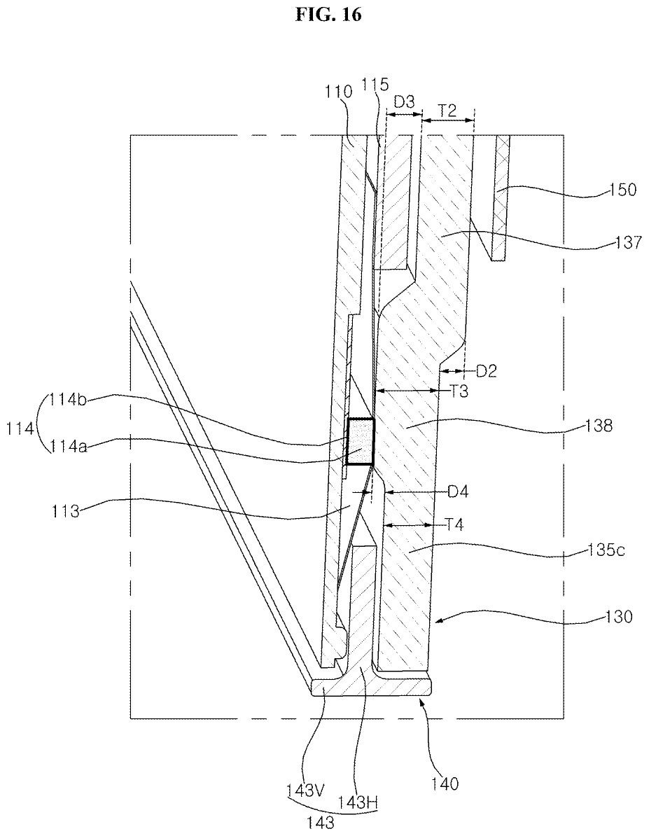

Referring to FIG. 16 along with FIG. 15, the display panel 110 may be coupled or fixed onto the side frame 140. The horizontal part 143H of the side frame 140 of the side frame 140 may support the rear surface of the display panel 110, and the vertical part 143V thereof may cover the side surface of the display panel 110. For example, the vertical part 143V of the third part 143 of the side frame 140 may cover the side surface of the lower side of the display panel 110.

The vertical part 143V may cover the side surface of the material complexed panel 130. For example, the vertical part 143V of the third part 143 of the side frame 140 may cover the side surface of the third outer part 135c of the material complexed panel 130.

A flexible cable 113 may extend from the lower side of the display panel 110 at a position between the display panel 110 and the vertical part 143H of the side frame 140. The flexible cable 113 may extend between the rear surface of the display panel 110 and the material complexed panel 130. For example, the flexible cable 113 may be a COF 113.

A source signal board 115 may be electrically connected to the flexible cable 113. The source signal board 115 may be fixed to one surface of the flexible cable 113. For example, the source signal board 115 may be an S-PCB 115. The source signal board 115 may be disposed in the receiving part 137 of the material complexed panel 130.

The flexible cable 113 may be disposed between the protruding pad 138 of the material complexed panel 130 and the display panel 110. The flexible cable 113 may make contact with the protruding pad 138. Heat generated by the source signal board 115 and/or the flexible cable 113 may be dissipated through the protruding pad 138.

A heat dissipation pad 114 may be disposed between the rear surface of the display panel 110 and the flexible cable 113 which make contact with the protruding pad 138. The heat dissipation pad 114 may include an elastic material 114a and a conductive film 114b. The core 114a of the heat dissipation pad 114 may be formed of an elastic material, and the conductive film 114b may cover the core 114a of the heat dissipation pad 114. Accordingly, the flexible cable 113 may be maintained in contact with the protruding pad 138.

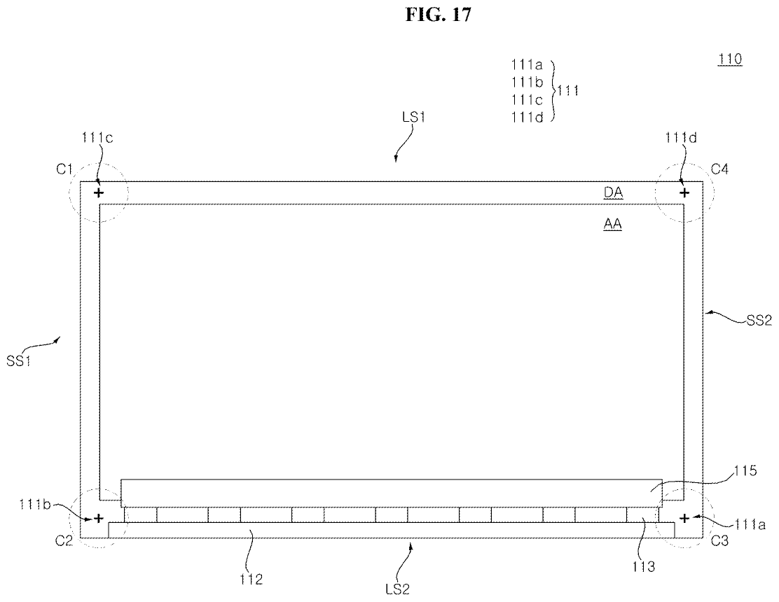

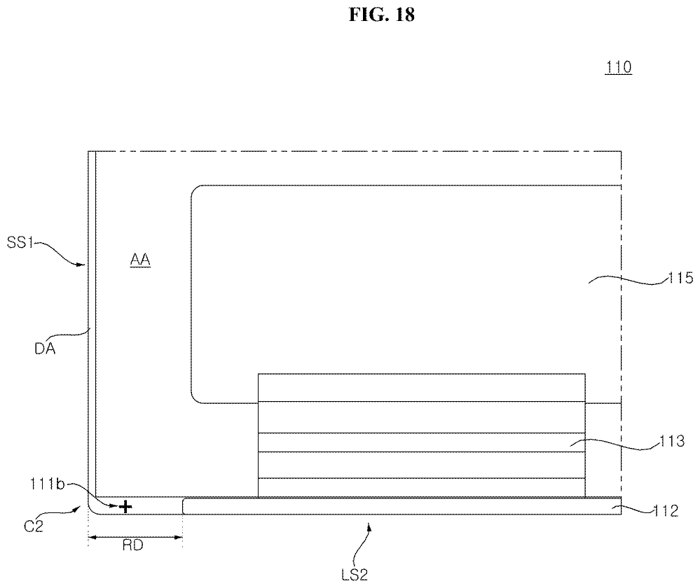

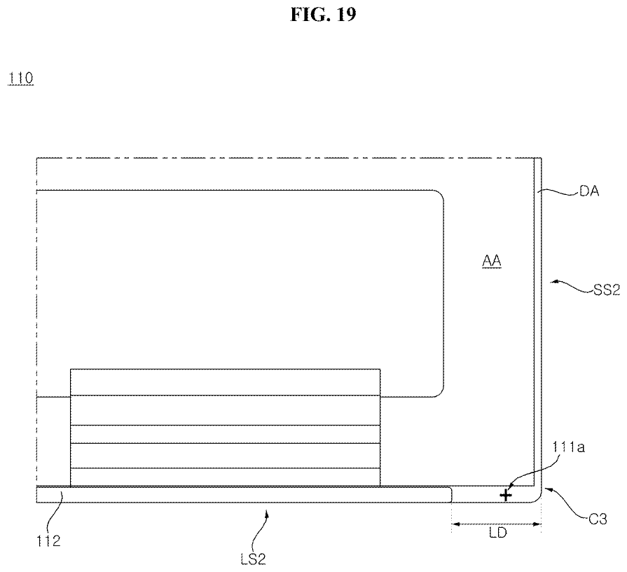

Referring to FIGS. 17 to 19, the display panel 110 may include an active area AA and a de-active area DA. The de-active area DA may be disposed at the edge of the active area AA. The active area AA may display images. The de-active area DA may be referred to as a bezel DA of the display panel 110.

The flexible cable 113 may be connected to the lower side LS2 of the display panel 110. The source signal board 115 may be connected to the flexible cable 113. The source signal board 115 may provide an image signal to the display panel 110 through the flexible cable 113.

A sealing member 112 may be disposed in the de-active area DA of the display panel 110 along the lower side LS2 of the display panel 110. For example, the sealing member 112 may be formed by dispensing an insulating material into the bezel DA of the lower side LS2 of the display panel 110 and curing the insulating material. A length of the sealing member 112 may be shorter than a length of the lower side LS2 of the display panel 110. For example, a first distance RD may be formed between a right end of the sealing member 112 and the first short side SS1 of the display panel 110. In another example, a second distance LD may be formed between a left end of the sealing member 112 and the second short side SS2 of the display panel 110. The first distance RD may be substantially equal to the second distance LD.

A processing key 111 may be formed on a rear surface of the bezel DA at the respective corners C1, C2, C3, and C4 of the display panel 110. The processing key 111 may be labeling for mass production of the display panel 110. The display panel 110 may be produced by identifying the processing key 111. Due to the processing key 111, the first distance RD and the second distance LD may be formed at the bottom LS2 of the bezel DA on the rear surface of the display panel 110.

Referring to FIG. 20, water may condense on the display panel 110 and/or the side frame 140 depending on an operating environment of the display device 100. The condensed water may flow in a downward direction of the display device 100 along the front surface of the display panel 110 and/or the side frame 140.

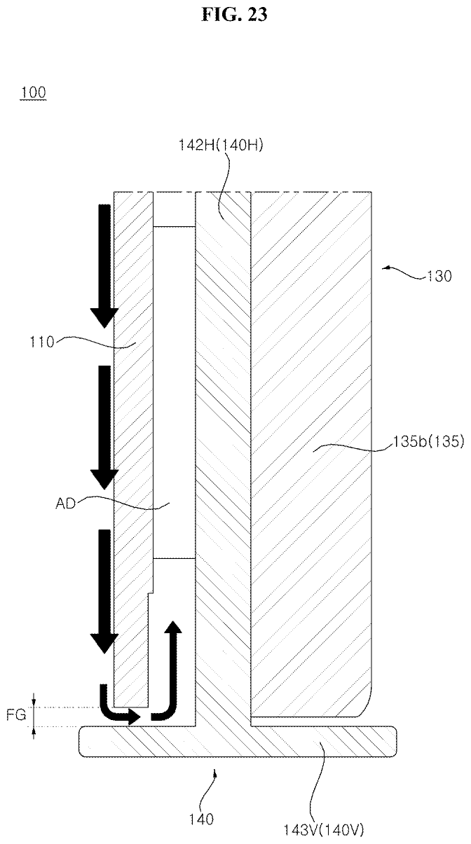

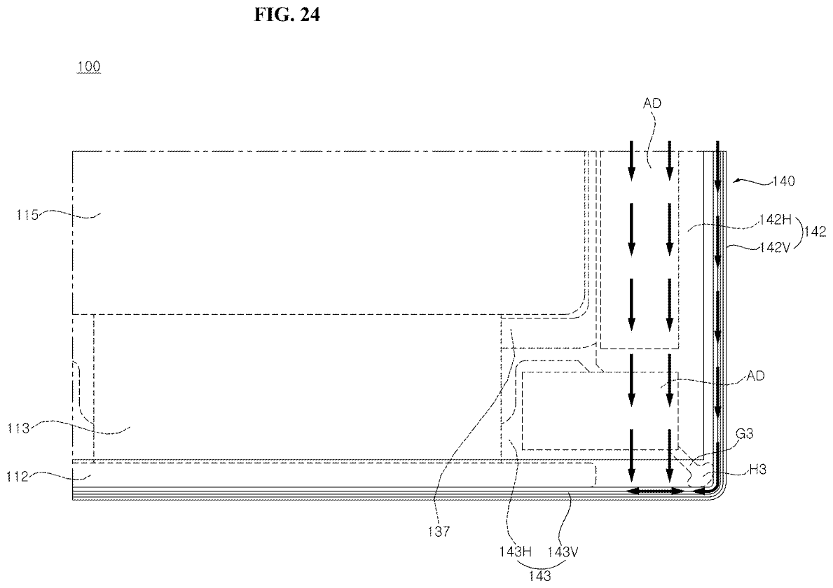

For example, water formed from condensed moisture may flow on the front surface of the display panel 110 or the side frame 140 in a downward direction of the first short side SS1 and/or the second short side SS2. The flowing water may condense on the lower side LS2 of the side frame 140 or at the corners C3 and C4, and the condensing water may be introduced between the display panel 110 and the side frame 140 (see FIG. 24) and/or between the display panel 110 and the material complexed panel 130 (see FIG. 23). The introduced water (moisture) may shorten the service life of the display panel 110. For example, circuit elements of the display panel 110 may be electrically short-circuited or burnt out.

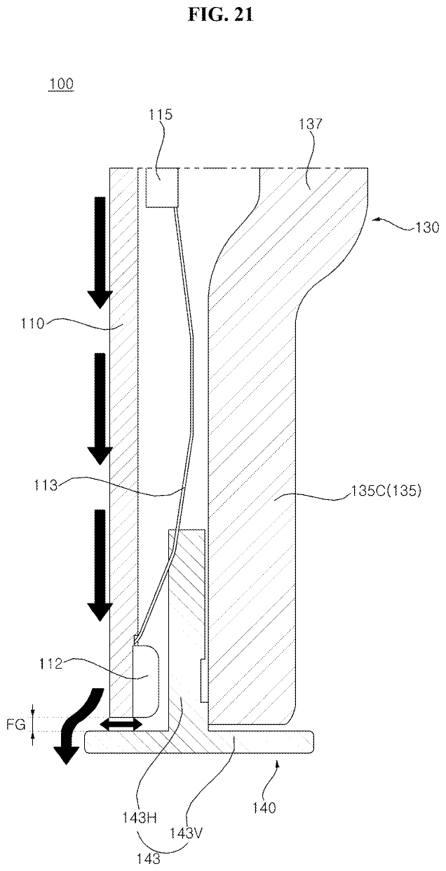

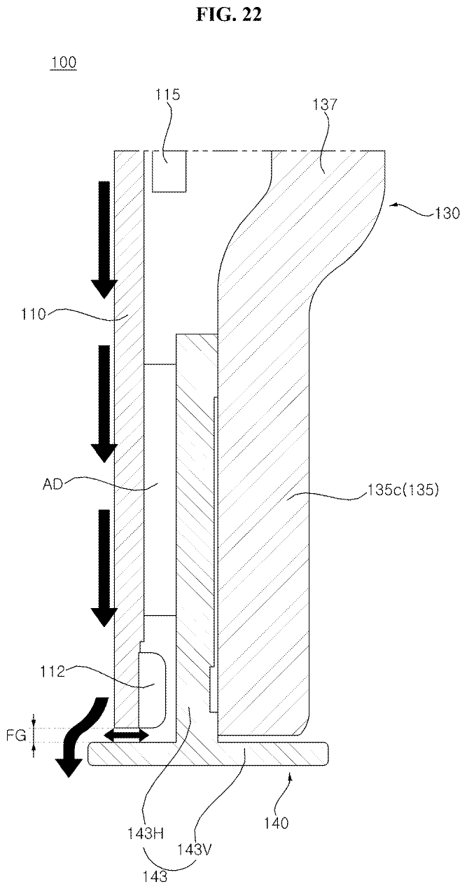

FIG. 21 is a diagram illustrating an example of a cross-section taken along line B-B′ of FIG. 20, and FIG. 22 is a diagram illustrating an example of a cross-section taken along line C-C′ of FIG. 20.

Referring to FIGS. 21 and 22, the display panel 110 may be disposed at the front of the material complexed panel 130. The side frame 140 and 143 may include the horizontal part 143H and the vertical part 143V. The horizontal part 143H of the side frame 140 and 143 may be disposed between the display panel 110 and the material complexed panel 130. For example, the horizontal part 143H of the side frame 140 and 143 may be fixed to a front surface of the outer part 135 and 135c of the material complexed panel 130.

The vertical part 143V of the side frame 140 and 143 may intersect the horizontal part 143H. The vertical part 143V may cover the side surface of the display panel 110 and/or the side surface of the material complexed panel 130. A gap FG may be formed between the side surface of the display panel 110 and the vertical part 143V. Moisture may be introduced into the gap FG formed between the side surface of the display panel 110 and the vertical part 143V. The sealing member 112 of the display panel 110 may block moisture or water introduced into the gap FG. The sealing member 112 may prevent circuit elements of the display panel 110 from being short-circuited or burnt out.

FIG. 23 is a diagram illustrating an example of a cross-section taken along line D-D′ of FIG. 20.

Referring to FIGS. 23 and 24, the display panel 110 may be disposed at the front of the material complexed panel 130. The side frames 140, 142, and 143 may include the horizontal parts 142H and 143H and the vertical parts 142V and 143V. The horizontal parts 142H and 143H of the side frames 140, 142, and 143 may be disposed between the display panel 110 and the material complexed panel 130. For example, the horizontal part 143H of the side frames 140, 142, and 143 may be fixed to the front surface of the third outer part 135c (see FIG. 6), and the horizontal part 142H may be fixed to the front surface of the second outer part 135b (see FIG. 6) of the material complexed panel 130.

The vertical parts 142V and 143V of the side frames 140, 142, and 143 may intersect the horizontal parts 142H and 143H thereof. The vertical parts 142V and 143V may cover the side surface of the display panel 110 and/or the side surface of the material complexed panel 130. The gap FG may be formed between the side surface of the display panel 110 and the vertical part 143V. For example, water or moisture may be introduced into the gap FG formed between the side surface of the display panel 110 and the vertical part 143V. The moisture or water introduced into the gap FG may cause the circuit elements of the display panel 110 to be short-circuited or burnt out.

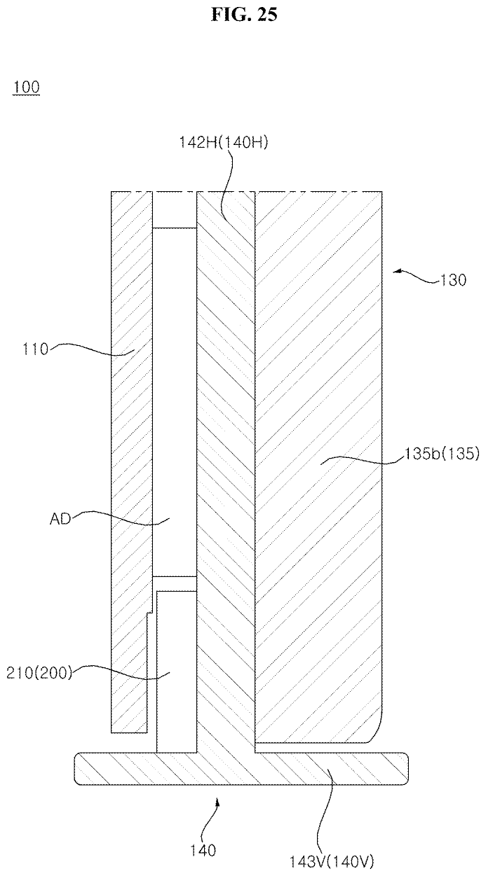

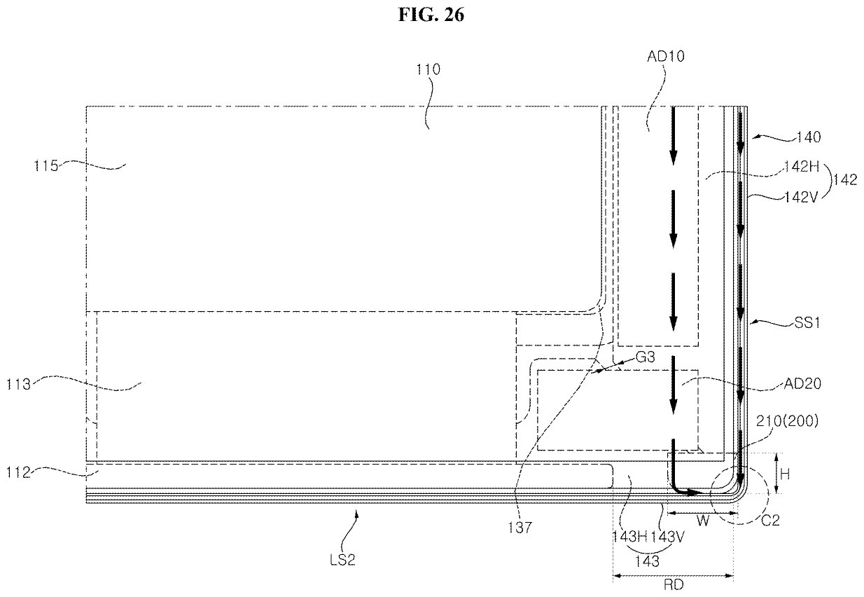

Referring to FIGS. 25 and 26, the horizontal part 142H of the second part 142 of the side frame 140 may be fixed onto the second outer part 135b (see FIG. 6) of the material complexed panel 130. The horizontal part 143H of the third part 143 of the side frame 140 may be fixed onto the third outer part 135c (see FIG. 6) of the material complexed panel 130. The vertical part 143V of the third part 143 of the side frame 140 may be bent and extend from the vertical part 142V of the second part 142.

An adhesive member AD10 may be fixed onto the horizontal part 142H of the second part 142 of the side frame 140. The adhesive member AD10 may be elongated in a longitudinal direction of the second part 142 of the side frame 140. An adhesive member AD20 may be fixed onto the horizontal part 143H of the third part 143 and the horizontal part 142H of the second part 142. The adhesive member AD20 may cover a gap G3 formed between the horizontal part 142H of the second part 142 and the horizontal part 143H of the third part 143.

The display panel 110 may be fixed to the side frame 140 by the adhesive members AD10 and AD20. The source signal board 115 is received in the receiving part 137, to be disposed between the material complexed panel 130 and the display panel 110. The sealing member 112 of the display panel 110 may face the horizontal part 143H of the third part 143 and may be parallel to the vertical part 143V of the third part 143. The sealing member 112 of the display panel 110 may be disposed between the adhesive member AD20, fixed to the horizontal part 142H of the second part 142 and the horizontal part 143H of the third part 143, and the vertical part 143V of the third part 143. The first distance RD of the display panel may be located at the second corner C2 where the first short side SS1 and the second long side LS2 of the display panel 110 meet.

A hygroscopic member 210 may be disposed adjacent to the second corner C2. The hygroscopic memer 210 may be referred to as an absorbing member 210. The hygroscopic member 210 may have a height side H and a width side W. The hygroscopic member 210 may be fixed to the horizontal parts 142H and 143H while covering the horizontal part 142H of the second part 142 and the horizontal part 143H of the third part 143. For example, a size of the width side W may be greater than a size of the height side H.

The height side H of the hygroscopic member 210 may make contact with the vertical part 142V of the second part 142. The width side W of the hygroscopic member 210 may make contact with the vertical part 143V of the third part 143. For example, a length of the width side W of the hygroscopic member 210 may be greater than a half (½) of the first distance RD and smaller than ⅔ of the first distance RD. A portion of the hygroscopic member 210 may be disposed between the adhesive member AD20 and the vertical part 143V of the third part 143. For example, the hygroscopic member 210 may be a black absorber. In another example, the hygroscopic member 210 may be a black synthetic resin.

Accordingly, damage to the display panel 110, the flexible cable 113 and/or the source signal board 115 may be prevented which may be caused by entry of moisture.

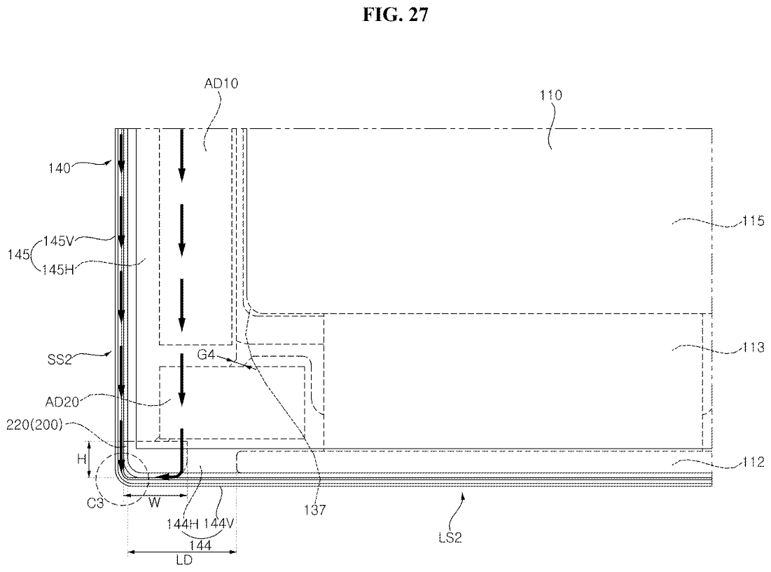

Referring to FIG. 27, a horizontal part 145H of the fifth part 145 of the side frame 140 may be fixed onto the fourth outer part 135d (see FIG. 6) of the material complexed panel 130. The horizontal part 144H of the fourth part 144 of the side frame 140 may be fixed onto the third outer part 135c (see FIG. 6) of the material complexed panel 130. The vertical part 144V of the fourth part 144 of the side frame 140 may be bent and extend from the vertical part 145V of the fifth part 145.

The adhesive member AD10 may be fixed onto the horizontal part 145H of the fifth part 145 of the side frame 140. The adhesive member AD10 may be elongated in a longitudinal direction of the fifth part 145 of the side frame 140. The adhesive member AD20 may be fixed onto the horizontal part 144H of the fourth part 144 and the horizontal part 145H of the fifth part 145. The adhesive member AD20 may cover a gap G4 formed between the horizontal part 144H of the fourth part 144 and the horizontal part 145H of the fifth part 145.

The display panel 110 may be fixed to the side frame 140 by the adhesive members AD10 and AD20. The source signal board 115 is received in the receiving part 137, to be disposed between the material complexed panel 130 and the display panel 110 (see FIG. 25). The sealing member 112 of the display panel 110 may face the horizontal part 144H of the fourth part 144 and may be parallel to the vertical part 144V of the fourth part 144. The sealing member 112 of the display panel 110 may be disposed between the adhesive member AD20, fixed to the horizontal part 144H of the fourth part 144 and the horizontal part 145H of the fifth part 143145, and the vertical part 144V of the fourth part 144. The second distance LD of the display panel 110 may be located at the third corner C2 where the second short side SS2 and the second long side LS2 of the display panel 110 meet.

A hygroscopic member 220 may be disposed adjacent to the third corner C3. The hygroscopic member 220 may have a height side H and a width side W. The hygroscopic member 220 may be fixed to the horizontal parts 144H and 145H while covering the horizontal part 144H of the fourth part 144 and the horizontal part 145H of the fifth part 145. For example, a size of the width side W may be greater than a size of the height side H.

The height side H of the hygroscopic member 220 may make contact with the vertical part 145V of the fifth part 145. The width side W of the hygroscopic member 220 may make contact with the vertical part 144V of the fourth part 144. For example, a length of the width side W of the hygroscopic member 220 may be greater than a half (½) of the second distance LD and smaller than ⅔ of the second distance LD. A portion of the hygroscopic member 220 may be disposed between the adhesive member AD20 and the vertical part 144V of the fourth part 144. For example, the hygroscopic member 220 may be a black absorber. In another example, the hygroscopic member 220 may be a black synthetic resin.

Accordingly, damage to the display panel 110, the flexible cable 113 and/or the source signal board 115 may be prevented which may be caused by entry of moisture.

Referring to FIGS. 1 to 27, a display device includes: a display panel 110 having at least one corner C1, C2, C3, and C4; a side frame 140 including a horizontal part 140H extending along one side LS2 of the display panel 110 from the at least one corner C1, C2, C3, and C4 and facing a rear surface of the display panel 110, and a vertical part 140V extending in a direction intersecting the horizontal part 140H and covering the one side LS2 of the display panel 110; and a hygroscopic member 200 making contact with the vertical part 140V and fixed to the horizontal part 140H at a position between the rear surface of the display panel 110, which is adjacent to the at least one corner C1, C2, C3, and C4, and the horizontal part 140H of the side frame 140.

The display panel 110 may include: an active area AA in which an image is displayed; and a de-active area DA forming a periphery of the active area AA, wherein the one side LS2 of the display panel 110 may form a side surface of the de-active area DA.

The display panel 110 may further include: a sealing member 112 elongated along the one side LS2 of the display panel 110, and fixed to the rear surface of the display panel 110 in the de-active area DA of the display panel 110; a flexible cable 113 connected to the display panel 110 at a position adjacent to the one side LS2 of the display panel 110, and electrically connected to the active area AA of the display panel 110; and a source signal board 115 electrically connected to the flexible cable 113, wherein a length of the sealing member 112 may be less than a length of the one side LS2 of the display panel 110.

The hygroscopic member 200 may be disposed in the de-active area DA of the display panel 110 at a position between the rear surface of the display panel 110, which is not covered by the sealing member 200 of the display panel 110, and the horizontal part 140H of the side frame 140.

The display device may further include a material complexed plate 130 including fibers, the material complexed plate 130 disposed at a rear of the display panel 110 and coupled with the side frame 140 and the display panel 110, wherein the material complexed plate 130 may include: a front skin 132 facing the display panel 110; a rear skin 133 facing the front skin 132; and a core 131 including the fibers and disposed between the front skin 132 and the rear skin 133.

The material complexed plate 130 may include: a flat plate part 130P facing a rear surface of the active area AA of the display panel 110; and an outer part 135 formed by recessing a front skin 132 of the flat plate part 130P and formed on a periphery of the flat plate part 130P, wherein the horizontal part 140H of the side frame 140 may be fixed to the outer part 135 of the material complexed plate 130.

The side frame 140 may include: first parts 143 and 144 positioned along the one side LS2 of the display panel 110; and second parts 142 and 145 positioned along other sides SS1 and SS2 of the display panel that are connected to the one side LS2 of the display panel 110 to form the corners C2 and C3, wherein the first parts 143 and 144 may include first horizontal parts 143H and 144H fixed to the outer part 135 of the material complexed plate 130 and facing the rear surface of the display panel 110, and first vertical parts 143V and 144V extending in a direction intersecting the first horizontal parts 143H and 144H and covering a side surface of the display panel 110; and the second parts 142 and 145 may include second horizontal parts 142H and 145H fixed to the outer part 135 of the material complexed plate 130 and facing the rear surface of the display panel 110, and second vertical parts 142V and 145V extending in a direction intersecting the second horizontal parts 142H and 145H and covering a side surface of the display panel 110, wherein the first vertical parts 143V and 144V may be bent and extend from the second vertical parts 142V and 145V, and the first horizontal parts 143H and 144H may form gaps G3 and G5 with the second horizontal parts 142H and 145H, wherein the hygroscopic member 200 may be fixed to the first horizontal parts 143H and 144H and the second horizontal parts 142H and 145H while covering the gaps G3 and G4.

The hygroscopic member 200 may have a side surface making contact with at least one of the first vertical part 143V and 144V and the second vertical part 142V and 145V.

The material complexed plate 130 may include: a flat plate part 130P facing a rear surface of the active area AA of the display panel 110; an outer part 135 formed by recessing the front skin 132 of the flat plate part 130P, to be stepped downward from the flat plate part 130P, and formed on the periphery of the flat plate part 130P; and a receiving part 137 disposed between the flat plate part 130P and the outer part 135, and formed by recessing the front skin 132 of the flat plate part 130P and the front skin 132 of the outer part 135, to be stepped downward from the flat plate part 130P and the outer part 135, wherein the source signal board 115 may be received in the receiving part 137.

The receiving part 137 may extend parallel to the sealing member 112 of the display panel 110.

Certain embodiments or other embodiments of the invention described above are not mutually exclusive or distinct from each other. Any or all elements of the embodiments of the invention described above may be combined or combined with each other in configuration or function.

For example, a configuration “A” described in one embodiment of the invention and the drawings and a configuration “B” described in another embodiment of the invention and the drawings may be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

What is claimed is:

1. A display device comprising:
a display panel including at least one corner;
a side frame including a horizontal part extending along one side of the display panel from the at least one corner and facing a rear surface of the display panel, and a vertical part extending in a direction intersecting the horizontal part and covering the one side of the display panel; and
a absorbing member being in contact with the vertical part and fixed to the horizontal part at a position between the rear surface of the display panel, which is adjacent to the at least one corner, and the horizontal part of the side frame.

2. The display device of claim 1, wherein the display panel comprises:
an active area displaying an image; and
a de-active area forming a periphery of the active area,
wherein the one side of the display panel forms a side surface of the de-active area.

3. The display device of claim 2, wherein the display panel furthers comprises:
a sealing member elongated along the one side of the display panel, and fixed to the rear surface of the display panel in the de-active area of the display panel;
a flexible cable connected to the display panel at a position adjacent to the one side of the display panel, and electrically connected to the active area of the display panel; and
a source signal board electrically connected to the flexible cable,
wherein a length of the sealing member is less than a length of the one side of the display panel.

4. The display device of claim 3, wherein the absorbing member is disposed in the de-active area of the display panel at a position between the rear surface of the display panel, which is not covered by the sealing member of the display panel, and the horizontal part of the side frame.

5. The display device of claim 1, further comprising a material complexed plate including fibers, the material complexed plate disposed at a rear of the display panel and coupled with the side frame and the display panel,
wherein the material complexed plate comprises:
a front skin facing the display panel;
a rear skin facing the front skin; and
a core including the fibers and disposed between the front skin and the rear skin.

6. The display device of claim 5, wherein the material complexed plate comprises:
a flat plate part facing a rear surface of the active area of the display panel; and
an outer part depressed down from a front skin of the flat plate part with a step and formed on a periphery of the flat plate part,
wherein the horizontal part of the side frame is fixed to the outer part of the material complexed plate.

7. The display device of claim 6, wherein the side frame comprises:
a first part positioned along the one side of the display panel; and
a second part positioned along another side of the display panel that is connected to the one side of the display panel to form the corner,
wherein:
the first part comprises a first horizontal part fixed to the outer part of the material complexed plate and facing the rear surface of the display panel, and a first vertical part extending in a direction intersecting the first horizontal part and covering a side surface of the display panel; and
the second part comprises a second horizontal part fixed to the outer part of the material complexed plate and facing the rear surface of the display panel, and a second vertical part extending in a direction intersecting the second horizontal part and covering a side surface of the display panel,
wherein the first vertical part is bent and extend from the second vertical part, and the first horizontal part form a gap with the second horizontal part,
wherein the absorbing member is fixed to the first horizontal part and the second horizontal part while covering the gap.

8. The display device of claim 7, wherein the absorbing member includes a side surface in contact with at least one of the first vertical part or the second vertical part.

9. The display device of claim 5, wherein the material complexed plate comprises:
a flat plate part facing a rear surface of the active area of the display panel;
an outer part depressed down from the front skin of the flat plate part with a step downward from the flat plate part, and formed on the periphery of the flat plate part; and
a receiving part disposed between the flat plate part and the outer part, and depressed down from the front skin of the flat plate part and the front skin of the outer part with a step downward from the flat plate part and the outer part,
wherein the source signal board is received in the receiving part.

10. The display device of claim 9, wherein the receiving part extends parallel to the sealing member of the display panel.
